(19) United States
(12) Patent Application Publication
(10) Pub. No.: US 2007/0013000 A1
(43) Pub. Date: Jan. 18, 2007

(54) Semiconductor device and manufacturing method of the same, and non-isolated DC/DC converter

(76) Inventor: Masaki Shiraishi, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/484,610

(22) Filed: Jul. 12, 2006

(30) Foreign Application Priority Data
Jul. 12, 2005 (JP) JP2005-203241

(51) Int. Cl. H01L 29/76

(52) U.S. Cl. 257/341

(57) ABSTRACT

In a low withstand voltage vertical trench MOSFET having an SJ structure, an N type epitaxial layer which is a current path and a trench structure which extends from a semiconductor surface into the N type epitaxial layer are provided, and a floating P type region is formed in a portion of the N type epitaxial layer positioned below the trench structure. The P type region is formed below the trench structure by ion-implanting P type impurity ions. By forming the P type region below a fine trench gate through ion-implantation, energy for ion-implantation can be reduced, and a fine SJ structure can be fabricated. Accordingly, a device structure which allow formation of a fine SJ structure in a low withstand voltage power MOSFET and a manufacturing method of the same can be provided.

### CROSS-REFERENCE TO RELATED APPLICATION

The present application claims priority from Japanese Patent Application No. JP 2005-203241 filed on Jul. 12, 2005, the content of which is hereby incorporated by reference into this application.

### TECHNICAL FIELD OF THE INVENTION

The present invention relates to a power MOSFET (metal oxide semiconductor-field effect transistor). In particular, it relates to a technology effectively applied to a device structure for realizing low ON resistance in a low withstand voltage power MOSFET and a manufacturing method of the same.

### BACKGROUND OF THE INVENTION

For example, it is known that a Super Junction structure (hereinafter, referred to as SJ structure) as shown in FIG. 11 is used as a power MOSFET having both high withstand voltage and low ON resistance (for example, U.S. Pat. No. 5,216,275 (Patent document 1)). FIG. 11 shows the SJ structure in a vertical trench MOSFET, in which P type regions 3 are formed in a columnar shape in an N type epitaxial layer 2 on an N⁺ substrate 1. As other constituent elements, the SJ structure includes a gate insulating film 4, a gate electrode 5, a channel region 6, a source region 7, a body contact region 8, a drain electrode 9, and a source electrode 10. In an OFF state, when voltage is applied between the drain and the source, a depletion region expands laterally from a PN junction extending in a vertical direction of the P type region 3 and the N type epitaxial layer 2, and both the P type region 3 and the N type epitaxial layer 2 are depleted. Therefore, the withstand voltage can be maintained. At that time, even if the resistivity of the N type epitaxial layer 2 is set to be lower than that of an ordinary power MOSFET, the withstand voltage can be maintained due to extension of the depletion layer in a lateral direction. As a result, the low ON resistance can be realized.

As a manufacturing method for forming the above SJ structure, the following three methods are well known.

(1) An SJ structure is fabricated by repeating the steps of growing a thin N type epitaxial layer on an N⁺ substrate, then ion-implanting P type impurities to form a P type region in the N type epitaxial layer, and growing a thin N type epitaxial layer thereon several times (for example, Japanese Patent Application Laid-Open Publication No. 2000-40822 (Patent document 2)).

(2) An SJ structure is formed by growing an N type epitaxial layer on an N⁺ substrate, then forming a deep trench which reaches the N⁺ substrate from a surface of the N type epitaxial layer, and epitaxially growing a P type region in the trench to embed the trench (for example, Japanese Patent Application Laid-Open Publication No. 2001-168327 (Patent document 3)).

(3) An SJ structure is formed by growing an N type epitaxial layer on an N⁺ substrate, and then performing multiple ion-implantation of P type impurities from a surface of the N type epitaxial layer with high energy of several MeV or more to form a P type region (for example, U.S. Pat. No. 6,586,798 (Patent document 4)).

### SUMMARY OF THE INVENTION

Incidentally, in a manufacturing method described in Patent document 2, there is such a problem that the number of process steps is increased because the SJ structure is separately formed through several steps, and a fine SJ structure cannot be formed because alignment margin between an N type region and a P type region is required.

Also, in a manufacturing method described in Patent document 3, there is such a problem that, since it is necessary to perform a deep silicon etching, a fine SJ structure cannot be formed and it is difficult to perform process control for embedding an epitaxial layer in a deep and narrow trench without gap.

Also, in a manufacturing method described in Patent document 4, there is such a problem that, since the SJ structure is formed by using the ion implantation with a high energy of several MeV or higher, the dispersion in a lateral direction at the time of ion implantation is large, and the fine SJ structure cannot be formed. Also, an ion-implantation apparatus for the high-energy implantation and a thick photoresist and insulating film for preventing the implantation leakage are required.

As described above, a common problem in the manufacturing methods of an SJ structure described in Patent documents 2 to 4 lies in that a fine SJ structure cannot be formed. However, it is necessary to form a fine SJ structure in order to apply the SJ structure to a low withstand voltage MOSFET. FIG. 12 shows a relationship between withstand voltage and ON resistance in an ordinary MOSFET and a MOSFET with an SJ structure reported by T. Fujihira et al. in ISPSD '98 (International Symposium on Power Semiconductor Device & ICs), pp. 423-426. In FIG. 12A, Si-Limit indicates a limit of low ON resistance of the ordinary MOSFET, and SJ Structure indicates dependency of an N type region and a P type region on their widths shown in FIG. 12B. It is understood from FIG. 12A and FIG. 12B that, unless widths of the N type region and the P type region are reduced to about 0.5 μm, it is not effective to apply the SJ structure to the power MOSFET with withstand voltage of about 30 V used in a non-isolated DC/DC converter in a power source circuit of a desktop PC, a notebook PC, a game machine and others. Also, since the SJ structure allows reduction in ON resistance, it is particularly effective to use the SJ structure as a low side switch of the non-isolated DC/DC converter.

As described above, the miniaturization of the SJ structure is necessary in order to apply the SJ structure to the low withstand voltage MOSFET, and the method using ion-implantation with high energy shown in the above item (3) is most suitable as the manufacturing method of the SJ structure. That is, in the method where the epitaxial growth and the ion-implantation are repeated as shown in the item (1) and in the method based upon the silicon etching and the epitaxial growth as shown in the item (2), it is difficult to form a fine SJ structure. Even in a method using ion-implantation with high energy, it is difficult to achieve the miniaturization due to the dispersion in a lateral direction during ion-implantation, but the dispersion in a lateral direction can be suppressed by lowering the energy for ion-implantation. More specifically, for applying the SJ structure to the low withstand voltage MOSFET, it is important to use a photomask as fine as possible and to reduce the energy for ion-implantation to form the SJ structure.

FIG. 13 is a cross-sectional view showing a power MOSFET having an SJ structure with withstand voltage of about 80 V, which has been reported by H. Ninomiya et al. in ISPSD '04, pp. 177-180. In FIG. 13, a P type region 3 is formed through ion-implantation with high energy of about 2 MeV from the surface, but the P type region 3 expands to 2.5 μm to 3 μm in depth and 1 μm to 2 μm in width. The P type region is generally formed by the ion-implantation of B (boron) and B disperses in a lateral direction in a range of about 0.2 μm when high energy of about 2 MeV is applied. Therefore, it is difficult to achieve the miniaturization (the P type region expands at least approximately 0.4 μm larger than a width of a photomask).

Furthermore, in FIG. 13, it is anticipated that the ion-implantation to form the P type region is performed by using a photomask which is also used for forming a body contact. However, when a width of the body contact layer is reduced in the structure shown in FIG. 13, breakdown tolerance is decreased. Therefore, it is difficult to use a fine photomask. Accordingly, it is difficult to directly apply this structure to a MOSFET with withstand voltage of about 30 V which requires a fine SJ structure of about 0.5 μm.

In view of these circumstances, an object of the present invention is to provide a device structure capable of forming a fine SJ structure in a low withstand voltage power MOSFET and a manufacturing method of the same.

The above and other objects and novel characteristics of the present invention will be apparent from the description of this specification and the accompanying drawings.

The typical ones of the inventions disclosed in this application will be briefly described as follows.

A feature of the present invention lies in that, in order to form a fine SJ structure, a P type region is formed below a trench gate through ion-implantation. More specifically, in a vertical trench MOSFET, a P type region is formed by utilizing a photomask for trench formation using the finest photomask and further performing ion-implantation below a trench gate formed by silicon etching. Therefore, since implantation energy can be lowered, a fine SJ structure can be fabricated.

Also, in the present invention, a P type region is formed through ion-implantation with high energy by utilizing a photomask which is also used for a body contact, in a structure where a high breakdown tolerance can be obtained even if a body contact region is made narrow.

Further, in the present invention, the N type drift layer is formed below the trench gate through the ion-implantation by using the P type epitaxial layer.

Specifically, the semiconductor device and the manufacturing method of the same according to the present invention are as follows. Note that names of respective constituent elements in the embodiments described later are enclosed between parentheses and attached to corresponding constituent elements constituting the present invention so as to associate these elements with each other.

(1) A semiconductor device according to the present invention comprises: a first semiconductor region (epitaxial layer) of a first conductivity type which is a current path; and a trench structure which extends from a semiconductor surface into the first semiconductor region, wherein a floating second semiconductor region (P type region) of a second conductivity type is formed in the first semiconductor region positioned below the trench structure. This second semiconductor region is formed by ion-implanting impurity ions of the second conductivity type to a portion below the trench structure.

(2) A semiconductor device according to the present invention comprises: a first semiconductor region (epitaxial layer) of a first conductivity type which is a current path; a third semiconductor region (channel region) of a second conductivity type positioned above the first semiconductor region; a first trench structure which extends from a semiconductor surface into the first semiconductor region through the third semiconductor region; a fourth semiconductor region (source region) of the first conductivity type positioned in the third semiconductor region; a second trench structure which extends from the semiconductor surface into the third semiconductor region; and a fifth semiconductor region (body contact region) of the second conductivity type which is positioned in the third semiconductor region just below the second trench structure, wherein a sixth semiconductor region (P type region) of the second conductivity type is formed in a portion of the first semiconductor region positioned below the second trench structure. This sixth semiconductor region is formed by ion-implanting impurity ions of the second conductivity type to a portion below the second trench structure.

(3) A semiconductor device according to the present invention comprises: a semiconductor substrate of a first conductivity type; an eighth semiconductor region (epitaxial layer) of a second conductivity type which epitaxially grows on the semiconductor substrate; a ninth semiconductor region (channel region) of the second conductivity type positioned above the eighth semiconductor region; and a gate structure which extends from a semiconductor surface into the eighth semiconductor region through the ninth semiconductor region, wherein a tenth semiconductor region (drift region) of the first conductivity type extending from the gate structure to the semiconductor substrate is formed below the gate structure. This tenth semiconductor region is formed by ion-implanting impurity ions of the first conductivity type to a portion below the gate structure.

The effects obtained by typical aspects of the present invention will be briefly described below.

According to the present invention, in the case where an SJ structure is applied to the low withstand voltage MOSFET, an SJ structure is fabricated through a multiple ion-implantation using a photomask which is also used to fabricate a fine trench gate. Therefore, energy for ion-implantation can be reduced and a fine SJ structure can be fabricated.

### BRIEF DESCRIPTIONS OF THE DRAWINGS

FIG. 1 is a diagram showing one example of a structure of a low withstand voltage vertical trench MOSFET having an SJ structure according to a first embodiment of the present invention;

FIG. 2A is a diagram showing one example of a manufacturing method of the low withstand voltage vertical trench MOSFET having an SJ structure according to the first embodiment of the present invention;

FIG. 2B is a diagram showing one example of a manufacturing method of the low withstand voltage vertical trench MOSFET having an SJ structure subsequent to FIG. 2A;

FIG. 2C is a diagram showing one example of a manufacturing method of the low withstand voltage vertical trench MOSFET having an SJ structure subsequent to FIG. 2B;

FIG. 3D is a diagram showing one example of a manufacturing method of the low withstand voltage vertical trench MOSFET having an SJ structure subsequent to FIG. 2C;

FIG. 3E is a diagram showing one example of a manufacturing method of the low withstand voltage vertical trench MOSFET having an SJ structure subsequent to FIG. 3D;

FIG. 3F is a diagram showing one example of a manufacturing method of the low withstand voltage vertical trench MOSFET having an SJ structure subsequent to FIG. 3E;

FIG. 4G is a diagram showing one example of a manufacturing method of the low withstand voltage vertical trench MOSFET having an SJ structure subsequent to FIG. 3F;

FIG. 4H is a diagram showing one example of a manufacturing method of the low withstand voltage vertical trench MOSFET having an SJ structure subsequent to FIG. 4G;

FIG. 4I is a diagram showing one example of a manufacturing method of the low withstand voltage vertical trench MOSFET having an SJ structure subsequent to FIG. 4H;;

FIG. 5 is a graph showing the calculation results of drain-source withstand voltages of the vertical trench MOSFET having an SJ structure according to the first embodiment of the present invention and an ordinary vertical trench MOSFET using an N type epitaxial layer with the same resistivity;

FIG. 6 is a diagram showing one example of a structure of a low withstand voltage vertical trench MOSFET having an SJ structure according to a second embodiment of the present invention;

FIG. 7A is a diagram showing one example of a manufacturing method of the low withstand voltage vertical trench MOSFET having an SJ structure according to the second embodiment of the present invention;

FIG. 7B is a diagram showing one example of a manufacturing method of the low withstand voltage vertical trench MOSFET having an SJ structure subsequent to FIG. 7A;

FIG. 7C is a diagram showing one example of a manufacturing method of the low withstand voltage vertical trench MOSFET having an SJ structure subsequent to FIG. 7B;

FIG. 7D is a diagram showing one example of a manufacturing method of the low withstand voltage vertical trench MOSFET having an SJ structure subsequent to FIG. 7C;

FIG. 8 is a diagram showing one example of a structure of a low withstand voltage vertical trench MOSFET having an SJ structure according to a third embodiment of the present invention;

FIG. 9A is a diagram showing one example of a manufacturing method of the low withstand voltage vertical trench MOSFET having an SJ structure according to the third embodiment of the present invention;

FIG. 9B is a diagram showing one example of a manufacturing method of the low withstand voltage vertical trench MOSFET having an SJ structure subsequent to FIG. 9A;

FIG. 9C is a diagram showing one example of a manufacturing method of the low withstand voltage vertical trench MOSFET having an SJ structure subsequent to FIG. 9B;

FIG. 9D is a diagram showing one example of a manufacturing method of the low withstand voltage vertical trench MOSFET having an SJ structure subsequent to FIG. 9C;

FIG. 10 is a diagram showing one example of a configuration of a non-isolated DC/DC converter using a low withstand voltage vertical trench MOSFET having an SJ structure, according to a fourth embodiment of the present invention;

FIG. 11 is a diagram showing one example of a structure of a conventional vertical trench MOSFET having an SJ structure;

FIG. 12A is a graph showing a relationship between withstand voltage and ON resistance based upon a theoretical limit and a width of an SJ structure of a conventional power MOSFET;

FIG. 12B is a diagram showing dependency of an N type region and a P type region on their widths; and

FIG. 13 is a diagram showing a structure of a low withstand voltage vertical trench MOSFET having an SJ structure formed by utilizing a conventional ion-implantation with high energy.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

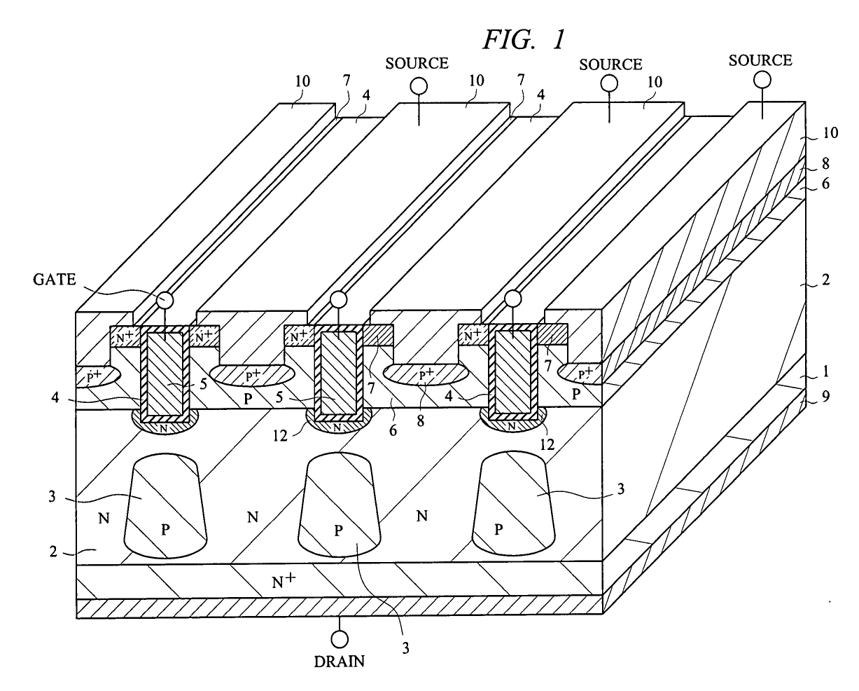

FIG. 1 shows one example of a structure of a low withstand voltage vertical trench MOSFET having an SJ structure according to a first embodiment of the present invention.

In the vertical MOSFET according to the first embodiment, an N type epitaxial layer 2, a P type region 3, a gate insulating film 4, a gate electrode 5, a channel region 6, a source region 7, a body contact region 8, and others are formed on an N⁺ substrate 1, a drain electrode 9 is formed on a rear surface thereof, and a source electrode 10 is provided on a front surface thereof.

The vertical MOSFET according to the first embodiment has a feature that the P type region 3 is formed in a floating state just below a trench gate. An ordinary P type region is connected to the channel region. In the first embodiment, however, since the P type region is formed just below the trench gate through the ion-implantation, the P type region is in a floating state. Although a stripe-shaped structure is shown in FIG. 1, a mesh-shaped structure such as a ladder-shaped structure or a hexagonal structure may be adopted.

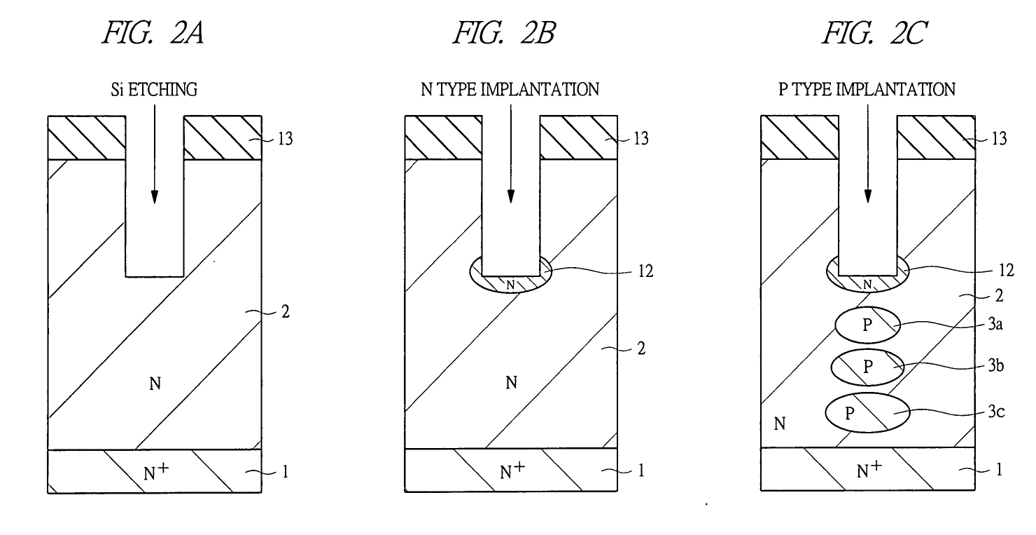

FIG. 2 to FIG. 4 show one example of a manufacturing method of the low withstand voltage vertical trench MOSFET having an SJ structure according to the first embodiment.

As shown in FIG. 2A, silicon etching for forming a trench gate is first performed with using an insulating film 13 as a mask in an N type epitaxial layer 2 which has grown on an N⁺ substrate 1. When a power MOSFET is fabricated, a photomask which allows maximum microfabrication is usually used for silicon etching, and the process dimensions thereof at present are in a range of about 0.2 μm to 0.3 μm.

Next, as shown in FIG. 2B, an N type region 12 is formed just below a trench through the ion-implantation of N type impurities. This is for preventing a P type region 3 formed later from connecting to a channel region 6. When the P type region 3 and the channel region 6 connect to each other, a current path is blocked and no current flows.

Next, as shown in FIG. 2C, P type regions 3a to 3c are formed by performing multiple ion-implantation of P type impurities. In the first embodiment, the ion-implantation is performed three times, but the number of times of the ion-implantation may be increased or decreased. In this case, since the ion-implantation is performed not from a semiconductor surface but just below the trench gate formed by the silicon etching, the implantation depth thereof can be made shallower by a depth of the trench gate in comparison with the case of ion-implantation performed from the surface.

In general, a thickness of an epitaxial layer in a power MOSFET with withstand voltage of about 30 V is in a range of about 2 μm to 4 μm, and a depth of a trench gate is in a range of about 0.5 μm to 1.5 μm. Considering an expansion due to the thermal diffusion, it is necessary to perform ion-implantation up to a depth of about 1.5 μm. In the case where B (boron) is adopted as the P type impurities, a P type region up to a depth of about 1.5 μm can be formed by the ion-implantation energy of about 500 keV.

The P type regions 3a to 3c shown in FIG. 2C are formed through the ion-implantation with the energies of 100 keV, 300 keV and 500 keV, respectively. Diffusion in a lateral direction when B is ion-implanted with energy of 500 keV is about 0.1 μm, and even if a width of the trench gate is added thereto, a fine P type region 3 of 0.4 μm to 0.5 μm can be formed. Also, even if it is assumed that the regions expand in the diffusion step, the width of the P type regions can be controlled within +0.5 μm or less of the width of the trench gate.

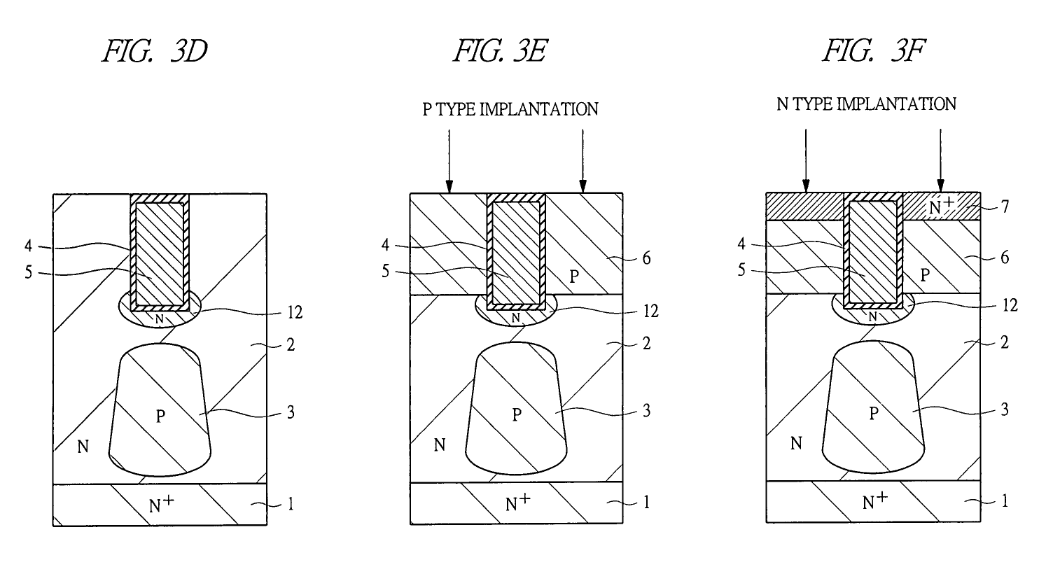

Next, as shown in FIG. 3D, a gate electrode 5 is formed via the gate insulating film 4, and as shown in FIG. 3E, a channel region 6 is formed by ion-implanting P type impurities. Then, a source region 7 is formed by ion-implanting N type impurities as shown in FIG. 3F.

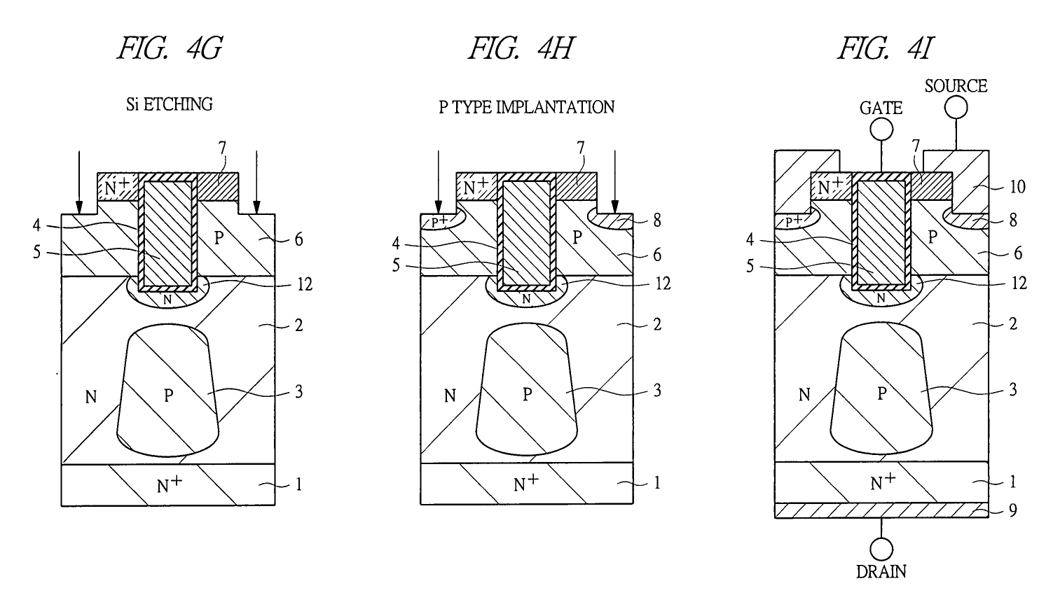

Next, as shown in FIG. 4G, silicon etching is performed for taking body contact. It is well known that miniaturization of a contact width and improvement of breakdown tolerance can be achieved by taking body contact with utilizing the trench obtained through the silicon etching. In the first embodiment, since the fabricated P type region has a size of about 0.5 μm, it is necessary to achieve the miniaturization of the N type epitaxial layer 2 to about 0.5 μm. Therefore, a body contact structure based upon the trench structure which allows the miniaturization of a cell size is adopted.

Next, as shown in FIG. 4H, a body contact region 8 is formed by performing ion-implantation of P type impurities, and a device structure according to the first embodiment shown in FIG. 4I is completed through a metal step.

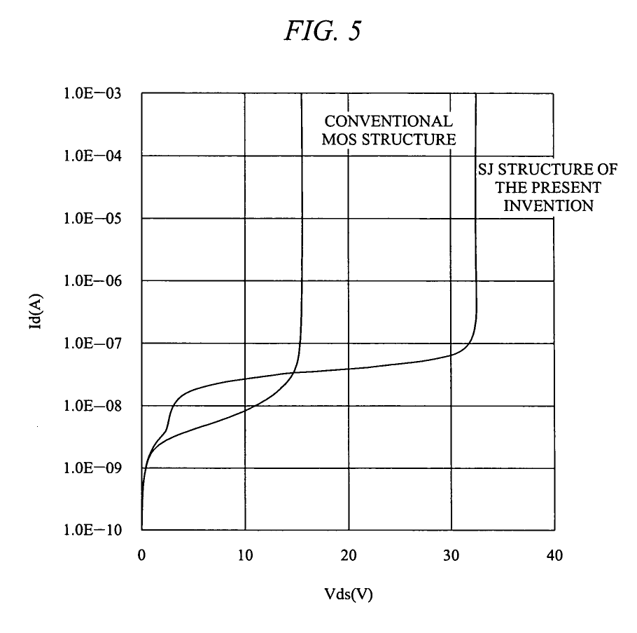

Incidentally, there is a concern about whether an advantage of high withstand voltage can be obtained in a floating P type region such as shown in the first embodiment. FIG. 5 shows calculation results of drain-source withstand voltages of an SJ structure having a P type region according to the first embodiment and an ordinary MOSFET including no P type region. Although leakage current slightly increases due to a floating structure, the withstand voltage is increased to about 33 V by forming a fine SJ structure of about 0.5 μm, whilst the withstand voltage is only about 15 V in the structure including no P type region as shown in FIG. 5. The resistivity of the epitaxial layer used in this calculation is reduced to about ¼ of that of an ordinary MOSFET with withstand voltage of about 30 V. That is, low ON resistance can be realized simultaneously with high withstand voltage.

### Second Embodiment

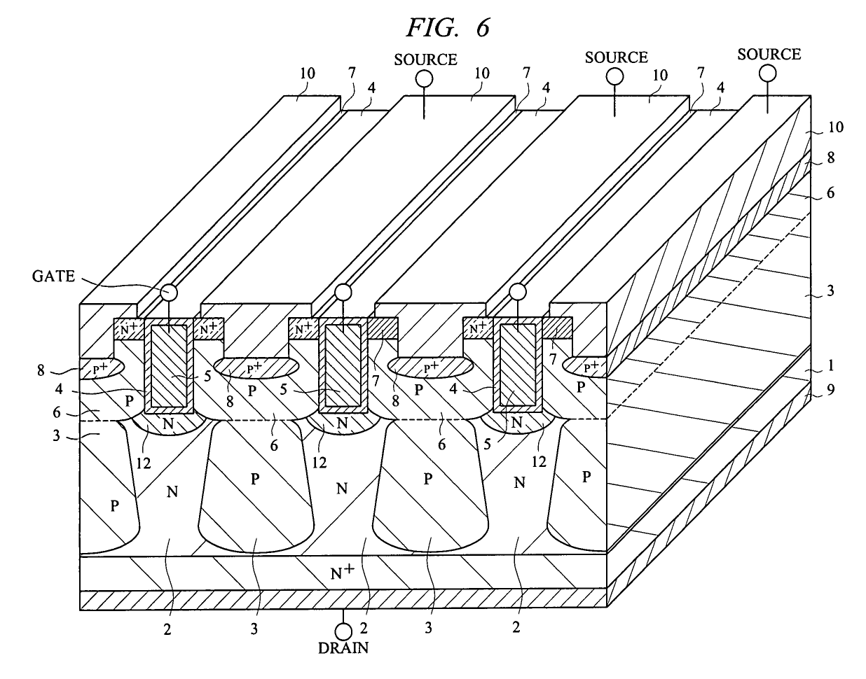

FIG. 6 shows one example of a structure of a low withstand voltage vertical trench MOSFET having an SJ structure according to a second embodiment of the present invention.

The difference between the vertical MOSFET according to the second embodiment and that of the first embodiment lies in the following point. That is, a P type region 3 is formed through the ion-implantation utilizing a photomask for silicon etching for taking body contact. Since the P type region is formed below the channel region, a depletion layer from the P type region expands more readily than the first embodiment, and thus, a leakage current can be reduced. Furthermore, since formation of the body contact is implemented in a latter part in an ordinary manufacturing process of a power MOSFET, there are only a few diffusion steps performed thereafter, and therefore, a width and a concentration of the P type region can be controlled more accurately.

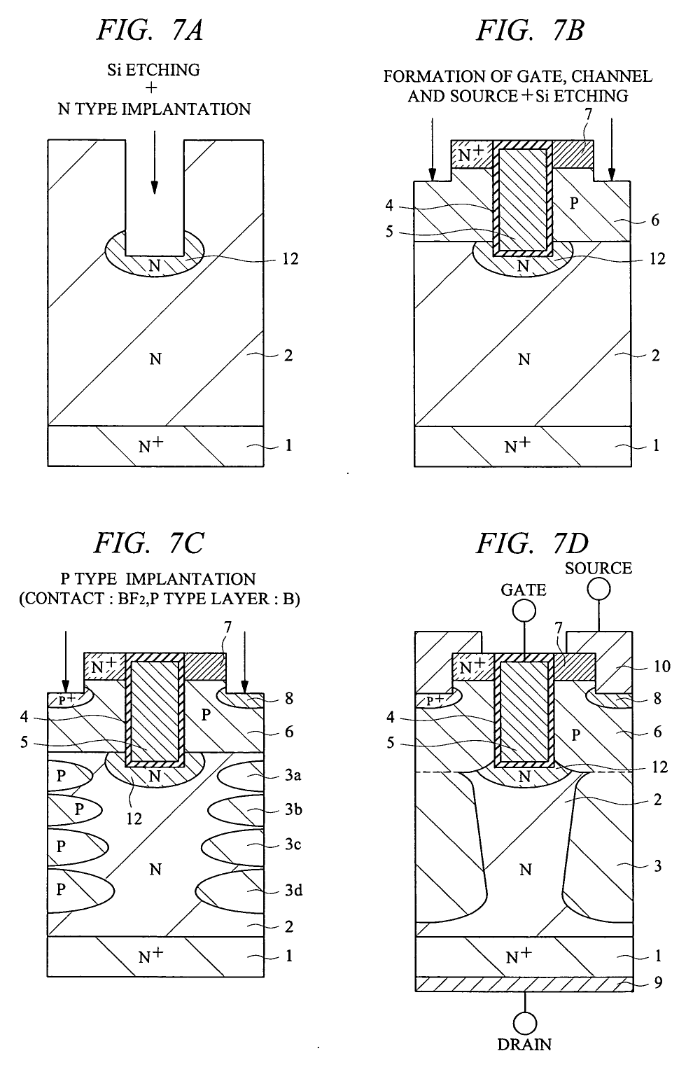

FIG. 7A to FIG. 7D show one example of a manufacturing method of a low withstand voltage vertical trench MOSFET having an SJ structure according to the second embodiment.

As shown in FIG. 7A, a trench gate is first formed through the silicon etching in an N type epitaxial layer 2 which has grown on an N⁺ substrate 1. Further, an N type region 12 is formed below a trench through the ion-implantation of N type impurities so that P type regions fabricated in a later step do not contact therewith just below the trench.

Next, as shown in FIG. 7B, a gate electrode 5, a channel region 6, and a source region 7 are formed. Thereafter, silicon etching for forming a body contact region is performed.

Next, as shown in FIG, 7C, P type regions 3a to 3d and a body contact region 8 are formed by utilizing a photomask for silicon etching to form the body contact region.

In the second embodiment, the number of diffusion steps performed after ion-implantation is reduced in comparison with that in the first embodiment. Therefore, the ion-implantation is performed four times in the second embodiment. However, the number may be increased or decreased. In this case, since the P type regions 3a to 3d are formed below the channel region 6 deeply in a certain extent and the body contact region 8 is formed just below the trench formed by the silicon etching, a P type impurity used to form the P type regions 3a to 3d and a P type impurity used to form the body contact 8 are different in ion species.

In FIG. 7A to FIG. 7D, B (boron) is ion-implanted with energies of 100 keV, 300 keV, 500 keV and 700 keV to form the P type regions 3a to 3d, and BF₂ is ion-implanted to form the body contact region 8. In the first embodiment, ion-implantation is performed below the trench gate, but in the second embodiment, ion-implantation is performed below the trench for forming the body contact region which is shallower than the trench gate. Therefore, ion-implantation is performed with energy higher than that in the first embodiment.

Furthermore, in FIG. 7A to FIG. 7D, the N type power MOSFET has been described. In the case of the P type power MOSFET, however, P (phosphorous) is used to form a deep N type region and As (arsenic) is used to form a shallow body contact region.

Thereafter, the device structure according to the second embodiment shown in FIG. 7D is completed through a metal step.

According to the second embodiment, since the P type region is formed below the channel region, a depletion layer from the P type region expands readily and a leakage current can be reduced. Also, since formation of the body contact is performed in a latter part of the manufacturing process, there are only a few diffusion steps performed thereafter, and therefore, a width and a concentration of the P type region can be controlled more accurately.

### Third Embodiment

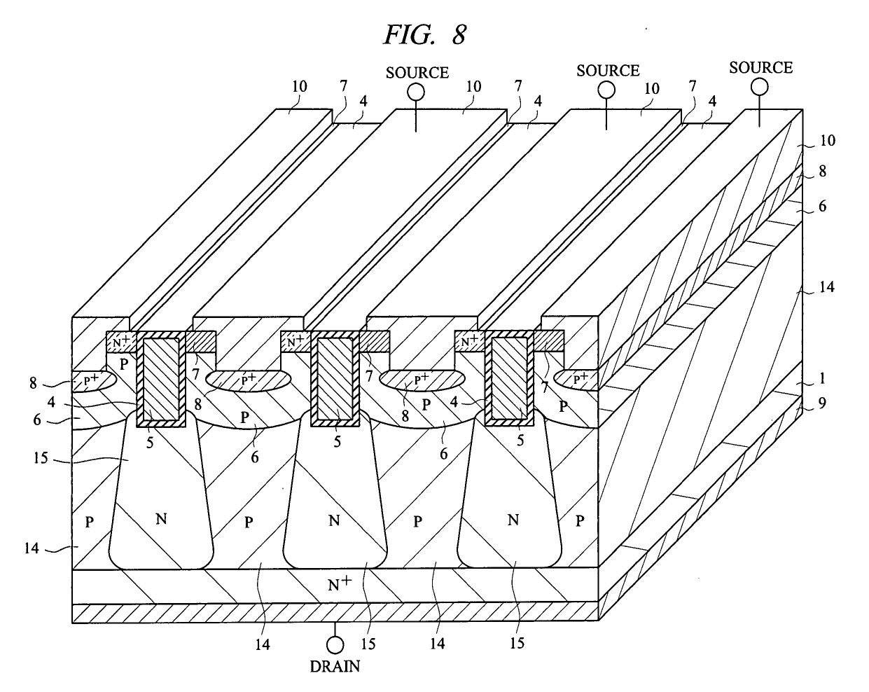

FIG. 8 shows one example of a structure of a low withstand voltage vertical trench MOSFET having an SJ structure according to a third embodiment of the present invention.

The difference between the vertical MOSFET according to the third embodiment and those of the first and second embodiments lies in the following point. That is, a feature of the third embodiment lies in that an N type drift region 15 is formed in a P type epitaxial layer 14 through the multiple ion-implantation. In the third embodiment, since an N type drift layer is formed just below the trench gate through the ion-implantation, an SJ structure can be fabricated by using a photomask which is also used to form a fine trench gate while maintaining the connection between the P type region and the channel region.

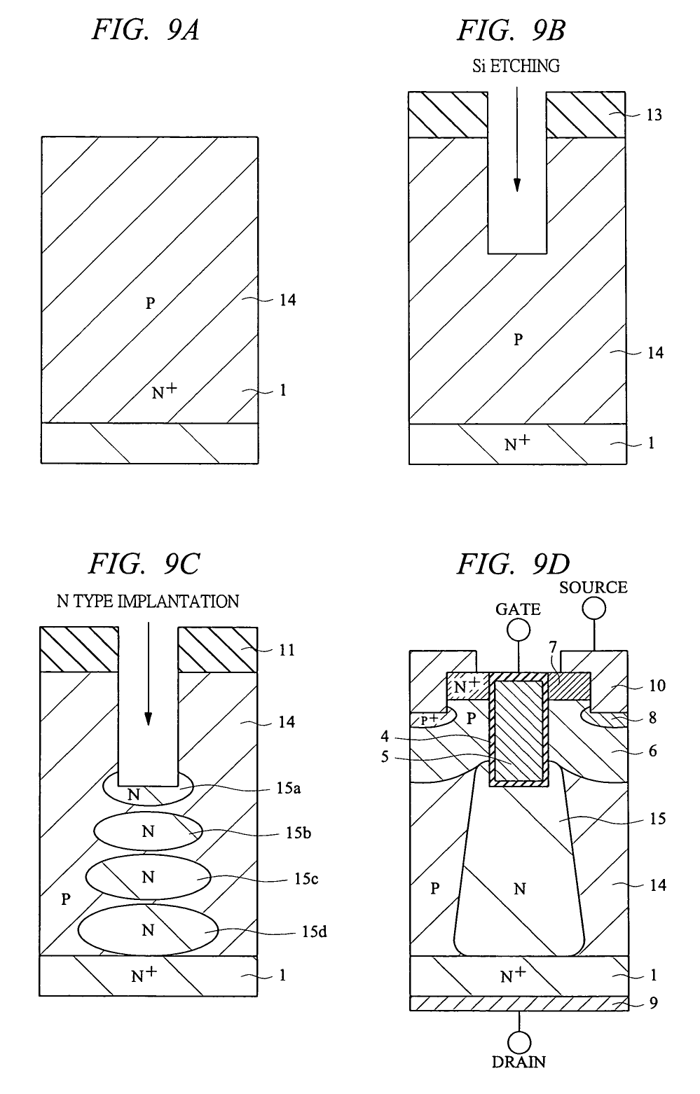

FIG. 9A to FIG. 9D show one example of a manufacturing method of a low withstand voltage vertical trench MOSFET having an SJ structure according to the third embodiment.

As shown in FIG. 9A, a P type epitaxial layer 14 first grows on an N⁺ substrate 1. The feature of the third embodiment lies in that the P type epitaxial layer 14 is used to form the N type drift region 15 in the P type epitaxial layer 14.

Next, as shown in FIG. 9B, silicon etching for forming a trench gate is performed with using an insulating film 13 as a mask. Similar to the case of the first embodiment, trench etching is performed with using the finest photomask of photomasks used in the manufacturing process of the power MOSFET, and the process dimensions thereof at present are in a range of about 0.2 μm to 0.3 μm.

Next, as shown in FIG. 9C, N type drift regions 15a to 15d are formed through the multiple ion-implantation of the N type impurities with using a photoresist 11 as a mask. In the third embodiment, ion-implantation is performed four times, but the number of times of the ion-implantation may be increased or decreased. Similar to the first embodiment, since the ion-implantation is performed not from a semiconductor surface but just below a trench gate formed by silicon etching, a depth of the implantation can be made shallower than that in the case where the implantation is performed from the surface by the depth of the trench gate, and implantation of about at most 1.5 μm is sufficient.

Note that a point different from the first embodiment lies in that N type impurities are used as ion species to be implanted to form an N type region and that the N type drift layer must be connected from a portion just below the trench gate to an N⁺ substrate 1. Since P (phosphorous) or As (arsenic) which is a representative N type impurity is shorter in ion range at the ion implantation than B (boron) which is a P type impurity, it is necessary to increase the implantation energy. In the example shown in FIG. 9C, As is implanted at the first stage and P is ion-implanted at the second and subsequent stages with the implantation energies of 200 keV, 600 keV, and 1 MeV, respectively.

Next, as shown in FIG. 9D, a gate electrode 5 is formed and a channel region 6 is formed (this step can be omitted depending on the concentration of the P type epitaxial layer 14 and the thickness of the gate insulating film 4). Then, a source region 7 is formed and silicon etching for forming a body contact region is performed to form a body contact region 8. Thereafter, through a metal step, a device structure according to the third embodiment is completed.

In the third embodiment, since the N type drift region is formed just below the trench gate by performing ion-implantation, an SJ structure can be fabricated by utilizing a photomask which is also used to form a fine trench gate while maintaining the connection between the P type region and the channel region.

### Fourth Embodiment

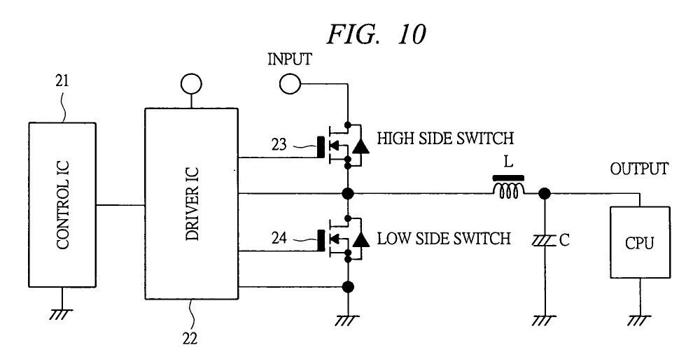

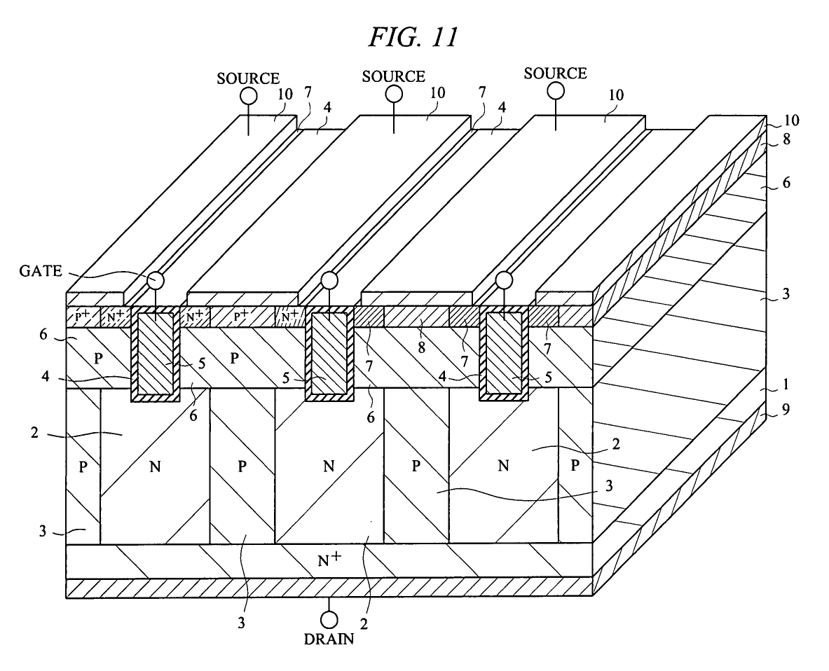

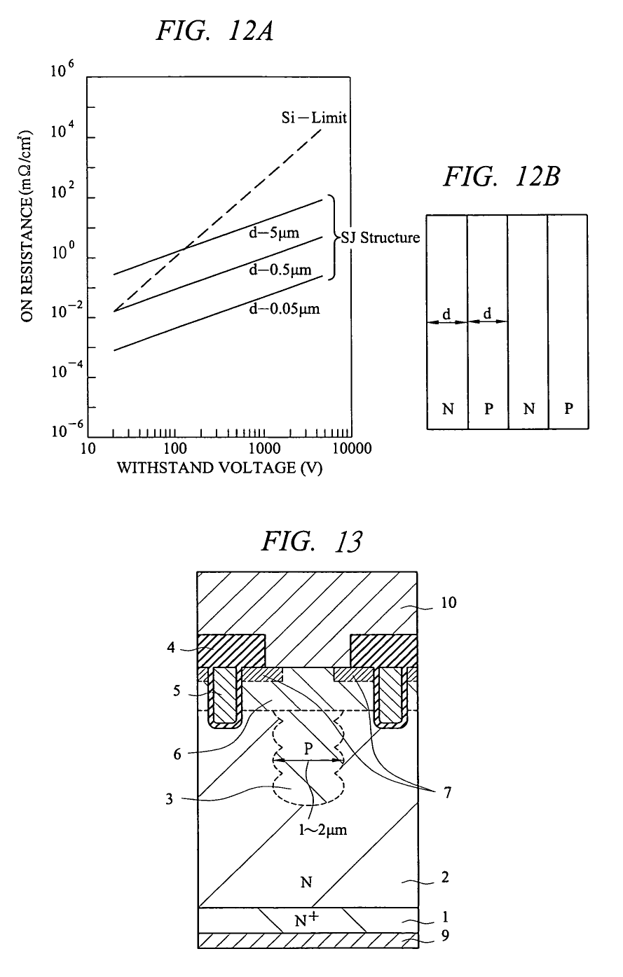

FIG. 10 shows one example of a configuration of a non-isolated DC/DC converter using a low withstand voltage vertical trench MOSFET having an SJ structure, according to a fourth embodiment of the present invention.

A non-isolated DC/DC converter according to the fourth embodiment is composed of a control IC 21, a driver IC 22, a high side switch 23, a low side switch 24, a smoothing inductor L, a smoothing capacitor C, and others, in which the power MOSFET according to the first, second, or third embodiment is used in the low side switch 24.

In the fourth embodiment, since an SJ structure is miniaturized and the SJ structure allows reduction of ON resistance, the power MOSFET can be effectively used as the low side switch 24 of a non-isolated DC/DC converter.

In the foregoing, the invention made by the inventor of the present invention has been concretely described based on the embodiments. However, it is needless to say that the present invention is not limited to the foregoing embodiments and various modifications and alterations can be made within the scope of the present invention.

Though the N type power MOSFET has been described in the above embodiments, for example, the present invention can be widely applied to a P type power MOSFET, a PN diode and a Schottky barrier diode having a trench structure, and other semiconductor devices.

The present invention relates to a power MOSFET. More particularly, it is effectively applied to a device structure of a low withstand voltage power MOSFET and a manufacturing method of the same, and it can be applied to various semiconductor devices having a trench structure.

What is claimed is:

1. A semiconductor device comprising: a first semiconductor region of a first conductivity type which is a current path; and a trench structure which extends from a semiconductor surface into said first semiconductor region,
wherein a floating second semiconductor region of a second conductivity type is formed in said first semiconductor region positioned below said trench structure.

2. The semiconductor device according to claim 1,
wherein said semiconductor device is a power MOSFET.

3. The semiconductor device according to claim 1,
wherein a length of said second semiconductor region in a lateral direction is equal or smaller than +0.5 μm of a length of said trench structure in the lateral direction.

4. The semiconductor device according to claim 1,
wherein a length of said first semiconductor region in a vertical direction is in a range of 2 μm or more to 4 μm or less.

5. A manufacturing method of a semiconductor device comprising: a first semiconductor region of a first conductivity type which is a current path; and a trench structure which extends from a semiconductor surface into said first semiconductor region,
wherein a floating second semiconductor region of a second conductivity type is formed in said first semiconductor region positioned below said trench structure, and
said second semiconductor region is formed below said trench structure by performing ion-implantation of impurity ions of the second conductivity type.

6. The manufacturing method of a semiconductor device according to claim 5,
wherein said ion-implantation of said impurity ions of the second conductivity type is performed several times while changing implantation energy.

7. The manufacturing method of a semiconductor device according to claim 5,
wherein ion-implantation of impurity ions of the first conductivity type is also performed into a portion of said first semiconductor region positioned below said trench structure in addition to said impurity ions of the second conductivity type.

8. The manufacturing method of a semiconductor device according to claim 7,
wherein an implantation depth of said impurity ions of the first conductivity type is shallower than an implantation depth of said impurity ions of the second conductivity type.

9. A semiconductor device comprising: a first semiconductor region of a first conductivity type which is a current path; a third semiconductor region of a second conductivity type positioned above said first semiconductor region; a first trench structure which extends from a semiconductor surface into said first semiconductor region through said third semiconductor region; a fourth semiconductor region of the first conductivity type positioned in said third semiconductor region; a second trench structure which extends from the semiconductor surface into said third semiconductor region; and a fifth semiconductor region of the second conductivity type which is positioned in said third semiconductor region just below said second trench structure,
wherein a sixth semiconductor region of the second conductivity type is formed in a portion of said first semiconductor region positioned below said second trench structure.

10. The semiconductor device according to claim 9,
wherein said semiconductor device is a power MOSFET.

11. The semiconductor device according to claim 9,
wherein a seventh semiconductor region of the first conductivity type is formed in a portion of said first semiconductor region positioned below said first trench structure.

12. The semiconductor device according to claim 9,
wherein a width of said sixth semiconductor region in a lateral direction is equal to or smaller than +0.5 μm of a width of said second trench structure in a lateral direction.

13. The semiconductor device according to claim 9,
wherein a length of said first semiconductor region in a vertical direction is in a range of 2 μm or more to 4 μm or less.

14. A manufacturing method of a semiconductor device comprising: a first semiconductor region of a first conductivity type which is a current path; a third semiconductor region of a second conductivity type positioned above said first semiconductor region; a first trench structure which extends from a semiconductor surface into said first semiconductor region through said third semiconductor region; a fourth semiconductor region of the first conductivity type positioned in said third semiconductor region; a second trench structure which extends from the semiconductor surface into said third semiconductor region; and a fifth semiconductor region of the second conductivity type which is positioned in said third semiconductor region just below said second trench structure,
wherein a sixth semiconductor region of the second conductivity type is formed in a portion of said first semiconductor region positioned below said second trench structure, and
said sixth semiconductor region is formed below said second trench structure by ion-implanting impurity ions of the second conductivity type.

15. The manufacturing method of a semiconductor device according to claim 14,
wherein said ion-implantation of said impurity ions of the second conductivity type is performed several times while changing implantation energy.

16. A semiconductor device comprising: a semiconductor substrate of a first conductivity type; an eighth semiconductor region of a second conductivity type which epitaxially grows on said semiconductor substrate; a ninth semiconductor region of the second conductivity type positioned above said eighth semiconductor region; and a gate structure which extends from a semiconductor surface into said eighth semiconductor region through said ninth semiconductor region,
wherein a tenth semiconductor region of the first conductivity type which extends from said gate structure to said semiconductor substrate is formed below said gate structure.

17. The semiconductor device according to claim 16,
wherein said semiconductor device is a power MOSFET.

18. The semiconductor device according to claim 16,
wherein a width of said tenth semiconductor region in a lateral direction is equal to or smaller than +0.5 μm of a width of said gate structure in the lateral direction.

19. The semiconductor device according to claim 16,
wherein a length of said eighth semiconductor region in a vertical direction is in a range of 2 μm or more to 4 μm or less.

20. A manufacturing method of a semiconductor device comprising: a semiconductor substrate of a first conductivity type; an eighth semiconductor region of a second conductivity type which epitaxially grows on said semiconductor substrate; a ninth semiconductor region of the second conductivity type positioned above said eighth semiconductor region; and a gate structure which extends from a semiconductor surface into said eighth semiconductor region through said ninth semiconductor region,
wherein a tenth semiconductor region of the first conductivity type which extends from said gate structure to said semiconductor substrate is formed below said gate structure, and
said tenth semiconductor region is formed below said gate structure by ion-implanting impurity ions of the first conductivity type.

21. The manufacturing method of a semiconductor device according to claim 20,
wherein said ion-implantation of said impurity ions of the first conductivity type is performed several times while changing implantation energy.

22. A non-isolated DC/DC converter,
wherein the power MOSFET according to claim 2 is used as a low side switch.
